(19) United States
(12) Patent Application Publication
(10) Pub. No.: US 2025/0306078 A1
(43) Pub. Date: Oct. 2, 2025

(54) ELECTRONIC DEVICE

(71) Applicant: Panasonic Automotive Systems Co., Ltd., Kanagawa (JP)

(72) Inventors: Shunsuke KATSUMURA, Tokyo (JP); Tatsuya INOUE, Osaka (JP); Hideaki TOKUNAGA, Osaka (JP); Keiji KOBAYASHI, Osaka (JP); Kenji NOZOE, Fukui (JP)

(21) Appl. No.: 19/088,561

(22) Filed: Mar. 24, 2025

(30) Foreign Application Priority Data
Mar. 29, 2024 (JP) 2024-057739

(51) Int. Cl. G01R 31/00; G01R 1/04

(52) U.S. Cl. CPC G01R 31/001; G01R 1/0416

(57) ABSTRACT

An electronic device includes a metal housing including a flat plate part, a connector terminal that projects from inside to outside through a through hole of the flat plate part of the metal housing and to which an electrical stress is applied, and a member that surrounds an outer periphery of the connector terminal along a direction in which the connector terminal projects, that is surrounded by an inner periphery of the flat plate part of the metal housing, and that is made of an electrostatic diffusion material.

### CROSS-REFERENCE TO RELATED APPLICATIONS

This application is based on and claims priority under 35 USC 119 from Japanese Patent Application No. 2024-057739 filed on Mar. 29, 2024, the entire content of which is incorporated herein by reference.

### TECHNICAL FIELD

The present disclosure relates to an electronic device.

### BACKGROUND ART

In the related art, an electronic device that reduces noise propagation is known. The electronic device includes: a circuit substrate on which an electric circuit is formed; a metal housing that houses the circuit substrate, is grounded to a ground, and is connected to a ground of the circuit substrate; an external connection terminal that projects from inside to outside of the metal housing, and connects an input terminal or an output terminal of the circuit substrate to the exterior; and an insulator that has at least a part thereof disposed between the metal housing and the external connection terminal, and insulates the metal housing and the external connection terminal from one another. A housing extension part, which extends from a body part of the metal housing in an inward direction or in an outward direction with respect to the metal housing in a condition facing the external connection terminal, is formed in the metal housing. At least a part of the insulator is disposed between the external connection terminal and the housing extension part. (see JP2021-072333A).

In the electronic device, a failure or an erroneous operation may occur during, for example, the electrostatic discharge test, and a further improvement is required.

The present disclosure provides an electronic device in which an occurrence of the failure or the erroneous operation can be prevented.

### SUMMARY OF INVENTION

An electronic device includes a metal housing including a flat plate part, a connector terminal that projects from inside to outside through a through hole of the flat plate part of the metal housing and to which an electrical stress is applied, and a member that surrounds an outer periphery of the connector terminal along a direction in which the connector terminal projects, that is surrounded by an inner periphery of the flat plate part of the metal housing, and that is made of an electrostatic diffusion material.

An electronic device includes a metal housing including a flat plate part, and a connector terminal that projects from inside to outside through a through hole of the flat plate part of the metal housing and to which an electrical stress is applied. An area of the flat plate part is 900 cm² or less.

An electronic device includes a metal housing including a flat plate part, and a connector terminal that projects from inside to outside through a through hole of the flat plate part of the metal housing and to which an electrical stress is applied. A projecting length of the connector terminal projecting from the flat plate part to the outside is longer than 1 cm.

According to the present disclosure, an occurrence of a failure or an erroneous operation can be prevented.

### BRIEF DESCRIPTION OF DRAWINGS

FIG. 1 is a diagram illustrating a configuration example of an ESD test system;

FIG. 2 is another diagram illustrating a configuration example of the ESD test system;

FIG. 3 is a diagram illustrating an example of a relation between an area of a ground plate and a first peak of an ESD current waveform;

FIG. 4 is a diagram illustrating an example of ESD current waveforms for respective projecting lengths of a connector terminal;

FIG. 5A is a top view illustrating a first configuration example of an electronic device;

FIG. 5B is a cross-sectional view taken along a line A-A′ of FIG. 5A;

FIG. 6A is a top view illustrating a second configuration example of the electronic device;

FIG. 6B is a cross-sectional view taken along a line B-B′ of FIG. 6A;

FIG. 7A is a top view illustrating a third configuration example of the electronic device;

FIG. 7B is a cross-sectional view taken along a line C-C′ of FIG. 7A; and

FIG. 8 is a diagram illustrating an ESD current waveform.

### DESCRIPTION OF EMBODIMENTS

Hereinafter, an embodiment will be described in detail with reference to the drawings as appropriate. However, unnecessarily detailed description may be omitted. For example, detailed description of well-known matters and description of substantially the same configuration may be omitted. This is to avoid unnecessary redundancy of the following description and to facilitate understanding of those skilled in the art. It should be noted that the accompanying drawings and the following description are provided for those skilled in the art to fully understand the present disclosure, and are not intended to limit the subject matter described in the claims.

### (Findings as Basis of Present Disclosure)

An electronic device is subjected to an electrostatic discharge test to check a degree of resistance to static electricity. The electrostatic discharge test is also called an ESD test. ESD is an abbreviation for Electro Static Discharge. The ESD test is also referred to as an ESD gun test. The ESD test is, for example, a test complying with an international standard of IEC61000 Apr. 2. IEC is an abbreviation for International Electrotechnical Commission, and indicates an international standard conference. In the ESD test, an electrical stress is applied to a predetermined terminal of the electronic device to be tested, and a current flows through the predetermined terminal. A current waveform is obtained by measuring the current. This current waveform is referred to as a discharge current waveform of the ESD test or an ESD current waveform. The electrical stress is, for example, an electrostatic stress.

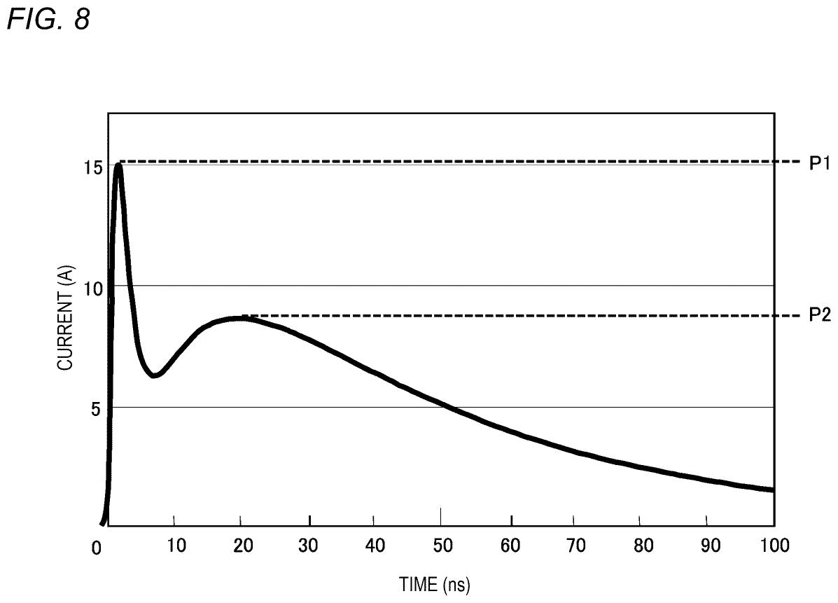

FIG. 8 is a diagram illustrating an example of the ESD current waveform. In FIG. 8, a horizontal axis represents time, and a vertical axis represents current. The ESD current waveform has a first peak P1 and a second peak P2 in chronological order. A breakdown or an erroneous operation of the electronic device to be tested may occur due to a current indicated by the first peak P1 itself or due to an energy at the second peak P2. The energy at the second peak P2 is correlated with an area of the second peak P2. The electronic device to be tested is also referred to as a DUT. The DUT is an abbreviation for Device Under Test. The first peak P1 is larger than the second peak P2. When the current at the first peak P1 is large, the breakdown or the erroneous operation of the electronic device to be tested may occur.

Therefore, when the current at the first peak P1 can be reduced, a possibility of an occurrence of the breakdown or the erroneous operation of the electronic device to be tested can be reduced. In order to reduce the current at the first peak P1, it is considered that it is effective to reduce a stray capacitance between an ESD gun, which applies the electrical stress to the electronic device to be tested, and the electronic device to be tested.

A reason will be described below. When the electrical stress is applied from the ESD gun to an external connection terminal of the electronic device, it is considered that a current value at the first peak P1 is increased due to a stray capacitance between a metal housing of the electronic device and the ESD gun. Therefore, it is required to reduce the stray capacitance between the electronic device and the ESD gun.

Hereinafter, an embodiment of an electronic device according to the present disclosure will be described with reference to the drawings.

### (First Embodiment)<Configuration of ESD Test System>

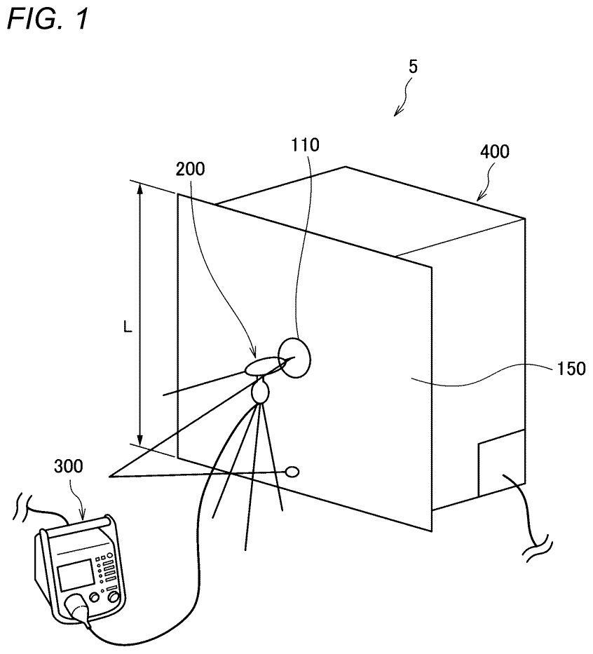

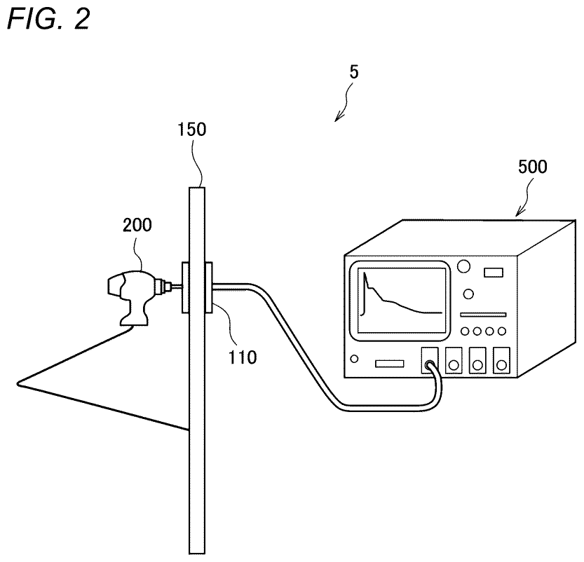

FIG. 1 is a diagram illustrating a configuration example of an ESD test system 5. FIG. 2 is another diagram illustrating a configuration example of the ESD test system 5. The ESD test system 5 includes, for example, a target 110, a ground plate 150, an ESD gun 200, a tester body 300, a Faraday gauge 400, and an oscilloscope 500. An illustration of the oscilloscope 500 is omitted in FIG. 1, and an illustration of the tester body 300 is omitted in FIG. 2.

The ESD test system 5 in FIGS. 1 and 2 has a same configuration as that of a general ESD test system for performing the ESD test complying with the standard of IEC61000 Apr. 2. A test environment and a test method of the ESD test are defined, for example, by the above standard. As will be described later, the ESD test system 5 can perform the ESD test while appropriately changing a size of the ground plate 150, and a height of the target 110 from the ground plate 150, that is, a projecting length.

The target 110 is conductive, and the electrical stress for test is applied from the ESD gun 200 to the target 110. The target 110 includes a member simulating a connector terminal of the electronic device and a ground part connected to the ground plate 150. The target 110 having different projecting lengths from the ground plate 150 is attached in the ESD test system 5 for the ESD test. The target 110 is attached to a front surface and a back surface of the ground plate 150, for example, at a central part of a plane of the ground plate 150.

The ground plate 150 is, for example, a flat plate-shaped member and is conductive. The ground plate 150 simulates the metal housing of the electronic device. The ground plates 150 of various sizes are attached in the ESD test system 5 for the ESD test, and characteristics of the ground plates 150 of various sizes are measured.

The ESD gun 200 is a discharge gun for discharging the static electricity. During the ESD test, a tip of the ESD gun 200 is brought into contact with the target 110 from a front surface side that is a side of the ESD gun 200 with respect to the ground plate 150. Then, the ESD gun 200 applies the electrical stress from the tip of the ESD gun 200 to the target 110 when, for example, a switch is pressed. A level of the applied electrical stress can be changed. For example, a return cable of the ESD gun 200 is connected to a ground terminal of the ground plate 150.

The tester body 300 charges a discharge capacitor of the ESD gun 200 at a predetermined voltage, for example. The predetermined voltage is, for example, 2 kV, 4 kV, 8 kV, or 15 kV, and may be another voltage. The ESD gun 200 generates a pulse by discharging a stored electric charge. The ESD gun 200 applies the generated pulse to the target 110 as the electrical stress. When the electrical stress applied from the ESD gun 200 is increased, a current indicated by the ESD current waveform obtained by the ESD test is also increased, and the first peak P1 and the second peak P2 tend to increase.

The Faraday gauge 400 is, for example, a device made of a conductor. An electromagnetic wave noise and an external electromagnetic wave are blocked inside the Faraday gauge 400. As illustrated in FIG. 1, the oscilloscope 500 may be disposed inside the Faraday gauge 400. In FIG. 2, the illustration of the Faraday gauge 400 is omitted.

The oscilloscope 500 is electrically connected to the target 110 attached to a back surface side of the ground plate 150 that is an opposite side of the ESD gun 200 with respect to the ground plate 150. The oscilloscope 500 measures a current flowing through the target 110. That is, the oscilloscope 500 measures the ESD current waveform. In this case, the oscilloscope 500 may directly measure the current flowing through the target 110, or may measure a voltage applied to an input impedance of the target 110 and calculate the current by dividing the voltage by a resistance value. The ESD current waveform may change depending on conditions of the target 110 and the ground plate 150.

<Consideration of Relation between Area of Ground Plate and First Peak>

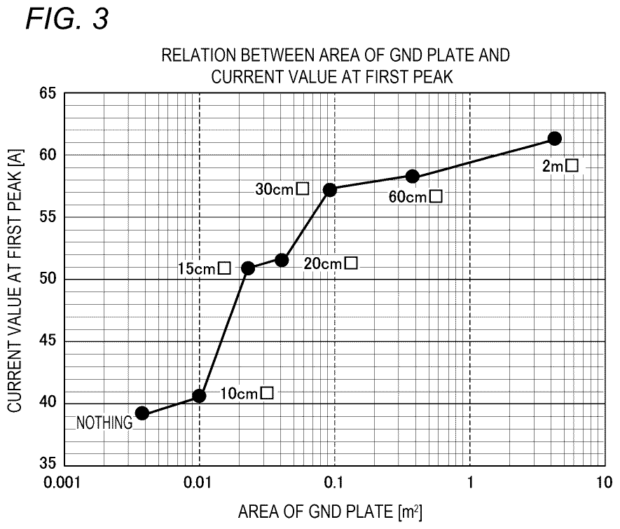

FIG. 3 is a diagram illustrating an example of a relation between an area of the ground plate 150 and the current value at the first peak P1 of the ESD current waveform. In FIG. 3, x m square, that is, x m×x m is described as “x m □”. For example, the area of the ground plate 150 is x² m² when expressed as x m square. In FIG. 3, an area of a GND plate, which is the area of the ground plate 150, indicated on a horizontal axis, is expressed logarithmically.

In the present embodiment, as illustrated in FIG. 3, current values at the first peak P1 at the time when the area of the ground plate 150 is 2 m square, 60 cm square, 30 cm square, 20 cm square, 15 cm square, 10 cm square, and 0 cm square, that is, the ground plate 150 is not provided are measured by the oscilloscope 500. Referring to FIG. 3, it can be understood that the current value at the first peak P1 is reduced as the area of the ground plate 150 is reduced. In particular, it can be estimated that the current value at the first peak P1 significantly is reduced, and a stray capacitance between the target 110 and the ground plate 150 and the ESD gun 200 is reduced when the area of the ground plate 150 is 30 cm square or less.

### <Consideration of Projecting Length of Target>

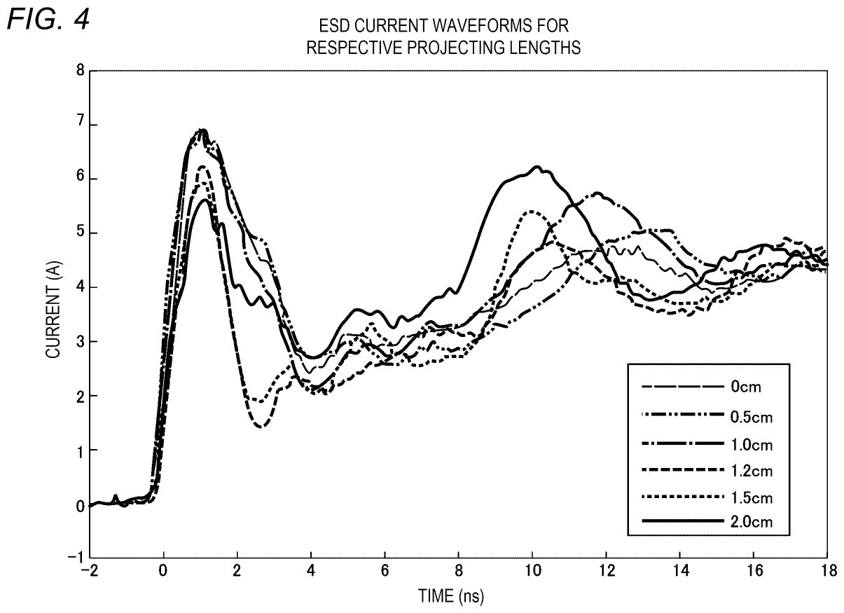

FIG. 4 is a diagram illustrating an example of ESD current waveforms for respective projecting lengths of the target 110. The ESD current waveform is indicated by a time from a discharge time of the ESD gun 200 and a current value of a discharge current.

In the present embodiment, as illustrated in FIG. 4, the ESD current waveforms at the time when the projecting length of the target 110 is 2.0 cm, 1.5 cm, 1.2 cm, 1.0 cm, 0.5 cm, and 0 cm are measured by the oscilloscope 500. Referring to FIG. 4, it can be understood that the current value at the first peak P1 present in a vicinity of 1 ns is reduced as the projecting length of the target 110 from the ground plate 150 is increased. This is because a distance between the ESD gun 200, which is brought into contact with the target 110 to apply the electrical stress, and the ground plate 150 is increased, and the stray capacitance is reduced as the projecting length of the target 110 from the ground plate 150 is increased. It can be estimated that the current value at the first peak P1 is reduced and the stray capacitance between the target 110 and the ESD gun 200 is reduced when the projecting length of the target 110 from the ground plate 150 is greater than 1.0 cm. In particular, it can be estimated that the current value at the first peak P1 is significantly reduced and the stray capacitance between the target 110 and the ESD gun 200 is significantly reduced when the projecting length of the target 110 from the ground plate 150 is greater than 1.2 cm.

Based on such consideration results, the present inventors focused attention on a fact that, when an electronic device 10 has the following configuration, a stray capacitance between the electronic device 10 simulated by the target 110 and the ground plate 150 and the ESD gun 200 can be reduced during an ESD test for the electronic device 10. According to the electronic device 10 having such a configuration, it can be expected that a failure or an erroneous operation of the electronic device 10 can be prevented.

The electronic device 10 may be, for example, an electronic device mounted on a vehicle, and an ECU or a power conversion device. The ECU is an abbreviation for Electronic Control Unit. The electronic device 10 may be an electronic device other than the electronic device mounted on the vehicle.

### <First Configuration Example of Electronic Device>

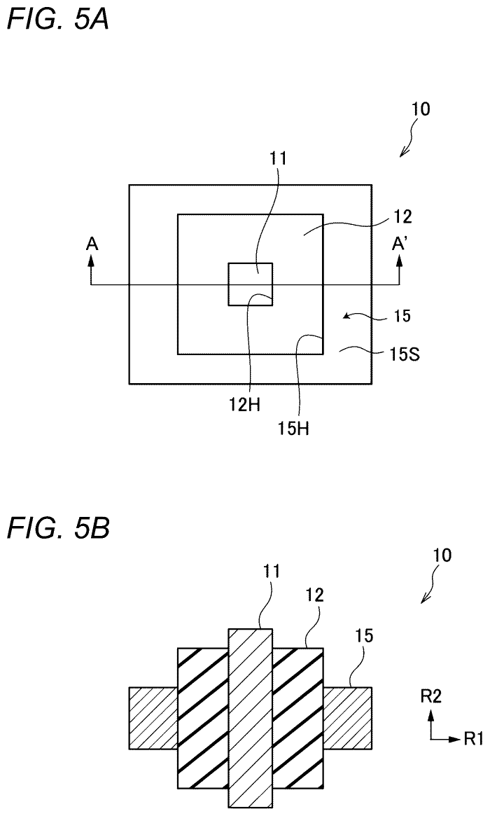

FIG. 5A is a top view illustrating the first configuration example of the electronic device 10. FIG. 5B is a cross-sectional view illustrating the first configuration example of the electronic device 10, and is a cross-sectional view taken along a line A-A′ of FIG. 5A.

In the first configuration example, the electronic device 10 includes a connector terminal 11, a predetermined member 12, and a metal housing 15.

The connector terminal 11 is a terminal to which the electrical stress is applied from the ESD gun 200 during the ESD test. The electrical stress is the same as the electrical stress applied to the target 110 described above. The connector terminal 11 is conductive.

The predetermined member 12 is a member having an electrical characteristic other than an insulator, and is, for example, a member made of an electrostatic diffusion material. The electrostatic diffusion material is a material having an electrical resistance value of 10⁴ Ω or more and less than 10¹¹ Ω. The predetermined member 12 is made of the electrostatic diffusion material, and thus has a characteristic of being able to release static electricity applied from the ESD gun 200, that is, a diffusion property. Accordingly, the predetermined member 12 can be prevented from being dielectrically broken down by repeatedly applying the static electricity from the ESD gun 200.

The metal housing 15 is conductive and is made of a metal such as aluminum.

The metal housing 15 has, for example, a box shape. The metal housing 15 has a flat plate part 15S. The flat plate part 15S has a through hole 15H, for example, at a central part, but may have the through hole 15H at a position other than the central part. In the through hole 15H, the connector terminal 11 and the predetermined member 12 are arranged in this order from an inner side, that is, from a center side of the hole. A substrate is provided inside the metal housing 15, and various electronic components are mounted on the substrate. The connector terminal 11, the predetermined member 12, and the metal housing 15 may be arranged coaxially. In FIGS. 5A and 5B, the flat plate part 15S of the metal housing 15 is illustrated as being rectangular when viewed from above, but may be another shape, for example, a circular shape. The flat plate part 15S may not be a completely flat plate. The flat plate part 15S may have a curvature larger than 0 in part or in whole, for example.

The connector terminal 11 extends in a direction R2 perpendicular to a direction R1 along the flat plate part 15S of the metal housing 15, and projects from inside to outside of the metal housing 15. In FIGS. 5A and 5B, the connector terminal 11 is illustrated as being rectangular when viewed from above, but may be another shape, for example, a circular shape.

In addition, inside the metal housing 15, the connector terminal 11 can be electrically connected to the electronic components on the substrate. The connector terminal 11 may be an external connection terminal that electrically connects the electronic components on the substrate and an external device outside the electronic device 10. The connector terminal 11 may be provided separately from the external connection terminal, and may be a dedicated terminal to which a predetermined electrical stress is applied from the ESD gun 200 during the ESD test. The connector terminal 11 may be electrically connected to the electronic components on the substrate even when the connector terminal 11 is the dedicated terminal.

The predetermined member 12 has a through hole 12H. The connector terminal 11 passes through the through hole 12H. The predetermined member 12 surrounds an outer periphery of the connector terminal 11 along the direction R2, is surrounded by an inner periphery of the flat plate part 15S that defines the through hole 15H, and is arranged coaxially with the connector terminal 11. In the direction R2, a thickness of the predetermined member 12 is smaller than a length of the connector terminal 11 and is larger than a thickness of the flat plate part 15S. In FIGS. 5A and 5B, the predetermined member 12 is illustrated as being rectangular when viewed from above, but may be another shape, for example, a circular shape.

In the first configuration example, the predetermined member 12 is made of the electrostatic diffusion material. The stray capacitance between the electronic device 10 and the ESD gun 200 can be reduced as compared with a case in which the predetermined member 12 of the electronic device 10 is made of an insulating material. Accordingly, the occurrence of the failure or the erroneous operation of the electronic device 10 can be prevented during, for example, the ESD test.

### <Second Configuration Example of Electronic Device>

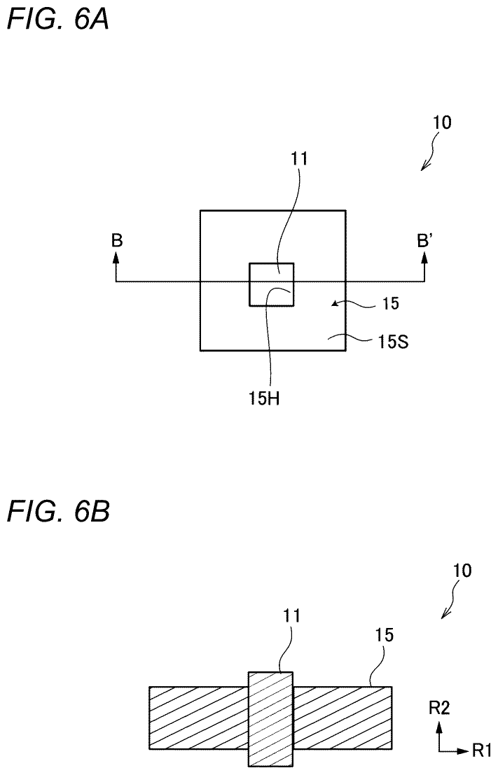

FIG. 6A is a top view illustrating the second configuration example of the electronic device 10. FIG. 6B is a cross-sectional view illustrating the second configuration example of the electronic device 10, and is a cross-sectional view taken along a line B-B′ of FIG. 6A. In the second configuration example, description for a configuration similar to the configuration illustrated in the first configuration example in FIGS. 5A and 5B may be omitted or simplified.

In the second configuration example, the electronic device 10 includes a connector terminal 11 and a metal housing 15. The electronic device 10 in the second configuration example is different from that in the first configuration example in that the predetermined member 12 is not provided and an area of the flat plate part 15S of the metal housing 15 is limited.

As illustrated in FIGS. 6A and 6B, the connector terminal 11 has a configuration similar to that in the first configuration example, but since the predetermined member 12 is not provided, the connector terminal 11 is surrounded by the flat plate part 15S of the metal housing 15. That is, the connector terminal 11 projects from the inside to the outside through the through hole 15H of the flat plate part 15S of the metal housing 15, and the electrical stress for performing the ESD test is applied to the connector terminal 11. The area of the flat plate part 15S is equal to or smaller than an area corresponding to a square in which each side is 30 cm, that is, is 900 cm² or less. The flat plate part 15S may be a square in which each side is 30 cm or less.

In the second configuration example, in the electronic device 10, since the area of the flat plate part 15S is 900 cm² or less, the first peak P1 can be significantly reduced as illustrated in FIG. 3. Accordingly, the stray capacitance between the electronic device 10 and the ESD gun 200 during the ESD test can be reduced. Accordingly, the occurrence of the failure or the erroneous operation of the electronic device 10 can be prevented during, for example, the ESD test. In addition, the electronic device 10 does not include the predetermined member 12, and thus can be made smaller.

### <Third Configuration Example of Electronic Device>

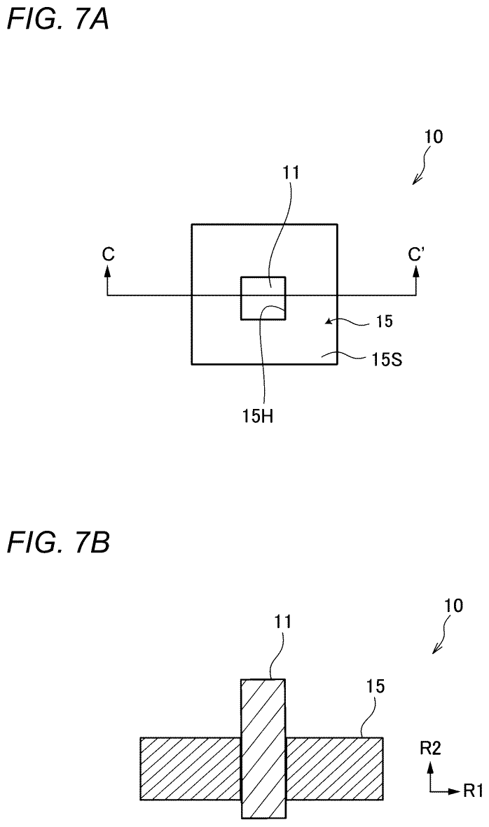

FIG. 7A is a top view illustrating the third configuration example of the electronic device 10. FIG. 7B is a cross-sectional view illustrating the third configuration example of the electronic device 10, and is a cross-sectional view taken along a line C-C′ of FIG. 7A. In the third configuration example, description for a configuration similar to the configuration illustrated in the first configuration example in FIGS. 5A and 5B or the configuration illustrated in the second configuration example in FIGS. 6A and 6B may be omitted or simplified.

In the third configuration example, the electronic device 10 includes the connector terminal 11 and the metal housing 15. The electronic device 10 in the third configuration example is different from that in the first configuration example in that the predetermined member 12 is not provided and a projecting length of the connector terminal 11 from the metal housing 15 is limited. The electronic device 10 in the third configuration example does not include the predetermined member 12, and is different from that in the second configuration example in that the area of the flat plate part 15S of the metal housing 15 is optional, and the projecting length of the connector terminal 11 from the metal housing 15 is limited. Specifically, the projecting length of the connector terminal 11 is longer than 1.0 cm, preferably 1.2 cm or more, and more preferably 1.5 cm or more.

In the third configuration example, since the projecting length of the connector terminal 11 from the metal housing 15 in the electronic device 10 is longer than 1.0 cm, the distance between the metal housing 15 and the ESD gun 200 is increased. Accordingly, as illustrated in FIG. 4, according to the electronic device 10, the stray capacitance between the electronic device 10 and the ESD gun 200 can be reduced, and the current value at the first peak P1 can be reduced. In particular, in the electronic device 10, when the projecting length of the connector terminal 11 is 1.2 cm or more, the current value at the first peak P1 can be further reduced. Accordingly, the occurrence of the failure or the erroneous operation of the electronic device 10 can be prevented during the ESD test. In addition, the electronic device 10 does not include the predetermined member 12, and thus can be made smaller.

In this way, it can be understood from the ESD test performed by the ESD test system 5 that the current in the ESD current waveform depends on the ground plate 150 simulating the metal housing 15 of the electronic device 10 and depends on the projecting length of the target 110 simulating the connector terminal 11 of the electronic device 10. Therefore, it can be estimated that the current in the ESD current waveform depends on the stray capacitance between the target 110 and the ground plate 150, which simulates the electronic device 10, and the ESD gun 200. With respect to this, the electronic device 10 has a configuration that reduces the stray capacitance by, for example, providing the predetermined member 12, limiting the area of the flat plate part 15S of the metal housing 15, or limiting the projecting length of the connector terminal 11. According to such an electronic device 10, a large current at the first peak P1 and the like in the ESD current waveform can be reduced, and a problem such as the failure of the erroneous operation can be reduced. For example, in the electronic device 10, an excessive current can be prevented from flowing, via the connector terminal 11, to the electronic components on the substrate inside the metal housing 15. Accordingly, in the electronic device 10, the failure or the erroneous operation of the electronic device 10 can be prevented.

In the present embodiment, a fact that the failure and the erroneous operation of the electronic device 10 can be prevented is described by taking an implementation of the ESD test as an example. Even in other situations, the failure or the erroneous operation of the electronic device 10 can be prevented. For example, according to the electronic device 10, a stray capacitance between an object that generates the electrical stress other than the ESD gun 200 and the electronic device 10 can be reduced. Accordingly, the failure or the erroneous operation of the electronic device 10 can be prevented. The object that generates the electrical stress other than the ESD gun 200 is, for example, a human hand.

### [Note]

The following techniques are disclosed according to the above description of the embodiment.

### (Technique 1)

An electronic device comprising:
a metal housing including a flat plate part;
a connector terminal that projects from inside to outside through a through hole of the flat plate part of the metal housing and to which an electrical stress is applied; and
a member that surrounds an outer periphery of the connector terminal along a direction in which the connector terminal projects, that is surrounded by an inner periphery of the flat plate part of the metal housing, and that is made of an electrostatic diffusion material.

The electronic device is, for example, the electronic device 10. The flat plate part is, for example, the flat plate part 15S. The metal housing is, for example, the metal housing 15. The through hole is, for example, the through hole 15H. The connector terminal is, for example, the connector terminal 11.

According to this configuration, in the electronic device, the outer periphery of the connector terminal is surrounded by the member made of the electrostatic diffusion material, rather than being surrounded by the metal housing. The stray capacitance between the electronic device and the ESD gun is reduced as compared with a case in which the electrostatic diffusion material is an insulating material and a case in which a part of the member made of the electrostatic diffusion material is also the metal housing. Accordingly, according to the electronic device, a large current at the first peak and the like in the ESD current waveform can be reduced, and the occurrence of the breakdown or the erroneous operation of the electronic device can be prevented.

### (Technique 2)

An electronic device comprising:
a metal housing including a flat plate part; and
a connector terminal that projects from inside to outside through a through hole of the flat plate part of the metal housing and to which an electrical stress is applied, wherein
an area of the flat plate part is 900 cm² or less.

According to this configuration, in the electronic device, since the area of the flat plate part is 900 cm² or less, the stray capacitance between the electronic device and the ESD gun can be reduced. Accordingly, according to the electronic device, the large current at the first peak and the like in the ESD current waveform can be reduced, and the occurrence of the breakdown or the erroneous operation of the electronic device can be prevented.

### (Technique 3)

The electronic device according to Technique 2, wherein
the flat plate part is smaller than a square in which each side is 30 cm.

According to this configuration, in the electronic device, the flat plate part of the metal housing can be easily produced, and the stray capacitance between the electronic device and the ESD gun can be reduced.

### (Technique 4)

An electronic device comprising:
a metal housing including a flat plate part; and
a connector terminal that projects from inside to outside through a through hole of the flat plate part of the metal housing and to which an electrical stress is applied, wherein
a projecting length of the connector terminal projecting from the flat plate part to the outside is longer than 1 cm.

According to this configuration, the connector terminal is separated from the metal housing by more than 1 cm, so that a distance between the ESD gun and the metal housing is increased during, for example, the electrostatic discharge test. Accordingly, the stray capacitance between the electronic device and the ESD gun is reduced. Accordingly, according to the electronic device, the large current at the first peak and the like in the ESD current waveform can be reduced, and the occurrence of the breakdown or the erroneous operation of the electronic device can be prevented.

### (Technique 5)

The electronic device according to Technique 4, wherein
the projecting length is 1.2 cm or more.

According to this configuration, the connector terminal is separated from the metal housing by 1.2 cm or more, so that the distance between the metal housing and the ESD gun is further increased during, for example, the electrostatic discharge test. Further, as illustrated in FIG. 4, it can be understood that when the projecting length of the connector terminal is 1.2 cm or more, the first peak corresponding to the projecting length can be easily identified and the first peak can be further reduced as compared with a case in which the projecting length is about 1.0 cm. Accordingly, the occurrence of the breakdown or the erroneous operation of the electronic device can be prevented.

### (Technique 6)

The electronic device according to Technique 5, wherein
the projecting length is 1.5 cm or more.

According to this configuration, the connector terminal is separated from the metal housing by 1.5 cm or more, so that the distance between the metal housing and the ESD gun is further increased during, for example, the electrostatic discharge test. Further, as illustrated in FIG. 4, it can be understood that when the projecting length of the connector terminal is 1.5 cm or more, the first peak corresponding to the projecting length can be easily identified, and the first peak can be further reduced. Accordingly, the occurrence of the breakdown or the erroneous operation of the electronic device can be prevented.

### (Technique 7)

The electronic device according to any one of Techniques 1 to 6, wherein
the connector terminal is electrically connected to an electronic component on a substrate provided inside the metal housing.

According to this configuration, in the electronic device, it is possible to prevent the large current at the first peak and the like from flowing into the metal housing via the connector terminal, and thus prevent the occurrence of the failure or the erroneous operation of the electronic component in the electronic device during, for example, the ESD test.

### (Technique 8)

The electronic device according to any one of Techniques 1 to 7, wherein
the electrical stress is an electrostatic stress for performing an electrostatic discharge test.

According to this configuration, in the electronic device, even when the electrostatic stress is applied to the connector terminal to perform the ESD test, the occurrence of the breakdown or the erroneous operation of the electronic device can be prevented.

### (Technique 9)

The electronic device according to any one of Techniques 1 to 8, wherein
the connector terminal is an external connection terminal that electrically connects the electronic component on the substrate provided inside the metal housing and an external device outside the electronic device.

According to this configuration, for example, the electronic device can be subjected to the ESD test using a configuration provided in advance in the electronic device without newly providing a terminal for performing the ESD test.

### (Technique 10)

The electronic device according to any one of Techniques 1 to 8, wherein
the connector terminal is a terminal different from an external connection terminal that electrically connects the electronic component on the substrate provided inside the metal housing and an external device outside the electronic device, and is a dedicated terminal to which an electrical stress is applied.

According to this configuration, for example, the electronic device can be subjected, by providing the terminal for performing the ESD test that is different from the external connection terminal, to the ESD test using, for example, an electrical stress that cannot be applied or is not recommended to be applied to the external connection terminal.

Although various embodiments have been described above with reference to the drawings, it is needless to say that the present invention is not limited to these embodiments. It is apparent that a person skilled in the art can conceive of various modifications or corrections within the scope described in the claims, and it is understood that such modifications or corrections naturally fall within the technical scope of the present invention. In addition, the components in the above embodiment may be freely combined in a range without deviating from the spirit of the invention.

### INDUSTRIAL APPLICABILITY

The present disclosure is useful in the electronic device or the like in which the occurrence of the failure or the erroneous operation can be prevented.

What is claimed is:

1. An electronic device comprising:
a metal housing including a flat plate part;
a connector terminal that projects from inside to outside through a through hole of the flat plate part of the metal housing and to which an electrical stress is applied; and
a member that surrounds an outer periphery of the connector terminal along a direction in which the connector terminal projects, that is surrounded by an inner periphery of the flat plate part of the metal housing, and that is made of an electrostatic diffusion material.

2. An electronic device comprising:
a metal housing including a flat plate part; and
a connector terminal that projects from inside to outside through a through hole of the flat plate part of the metal housing and to which an electrical stress is applied, wherein an area of the flat plate part is 900 cm² or less.

3. The electronic device according to claim 2, wherein
the flat plate part is smaller than a square in which each side is 30 cm.

4. An electronic device comprising:
a metal housing including a flat plate part; and
a connector terminal that projects from inside to outside through a through hole of the flat plate part of the metal housing and to which an electrical stress is applied, wherein
a projecting length of the connector terminal projecting from the flat plate part to the outside is longer than 1 cm.

5. The electronic device according to claim 4, wherein
the projecting length is 1.2 cm or more.

6. The electronic device according to claim 5, wherein
the projecting length is 1.5 cm or more.

7. The electronic device according to claim 1, wherein
the connector terminal is electrically connected to an electronic component on a substrate provided inside the metal housing.

8. The electronic device according to claim 2, wherein
the connector terminal is electrically connected to an electronic component on a substrate provided inside the metal housing.

9. The electronic device according to claim 4, wherein
the connector terminal is electrically connected to an electronic component on a substrate provided inside the metal housing.

10. The electronic device according to claim 1, wherein
the electrical stress is an electrostatic stress for performing an electrostatic discharge test.

11. The electronic device according to claim 2, wherein
the electrical stress is an electrostatic stress for performing an electrostatic discharge test.

12. The electronic device according to claim 4, wherein
the electrical stress is an electrostatic stress for performing an electrostatic discharge test.

13. The electronic device according to claim 7, wherein
the connector terminal is an external connection terminal that electrically connects the electronic component on the substrate provided inside the metal housing and an external device outside the electronic device.

14. The electronic device according to claim 8, wherein
the connector terminal is an external connection terminal that electrically connects the electronic component on the substrate provided inside the metal housing and an external device outside the electronic device.

15. The electronic device according to claim 9, wherein
the connector terminal is an external connection terminal that electrically connects the electronic component on the substrate provided inside the metal housing and an external device outside the electronic device.

16. The electronic device according to claim 7, wherein
the connector terminal is a terminal different from an external connection terminal that electrically connects the electronic component on the substrate provided inside the metal housing and an external device outside the electronic device, and is a dedicated terminal to which an electrical stress is applied.

17. The electronic device according to claim 8, wherein
the connector terminal is a terminal different from an external connection terminal that electrically connects the electronic component on the substrate provided inside the metal housing and an external device outside the electronic device, and is a dedicated terminal to which an electrical stress is applied.

18. The electronic device according to claim 9, wherein
the connector terminal is a terminal different from an external connection terminal that electrically connects the electronic component on the substrate provided inside the metal housing and an external device outside the electronic device, and is a dedicated terminal to which an electrical stress is applied.
